(19) United States
(12) Patent Application Publication
(10) Pub. No.: US 2007/0018335 A1
(43) Pub. Date: Jan. 25, 2007

(54) Polygonal, rounded, and circular flip chip ball grid array board

(75) Inventors: Seung-Hyun Cho, Seoul (KR); Soon-Jin Cho, Daejeon (KR); Jae-Joon Lee, Chungcheongbuk-do (KR); Se-Jong Oh, Gyeonggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/483,844

(22) Filed: Jul. 11, 2006

(30) Foreign Application Priority Data
Jul. 11, 2005 (KR) 10-2005-0062274

(51) Int. Cl. H01L 23/48

(52) U.S. Cl. 257/778; 257/E23.021

(57) ABSTRACT

A flip chip BGA board is disclosed, in which each of the corners of the board is removed to minimize warpage of the board due to heat applied during the manufacturing process. Embodiments of the invention allow the production of thin boards by preventing warpage of the board, and may provide a board high in reliability since the risk of the chip being separated from the board is reduced.

### CROSS-REFERENCE TO RELATED APPLICATIONS

This application claims the benefit of Korean Patent Application No. 2005-62274 filed with the Korea Industrial Property Office on Jul. 11, 2005, the disclosure of which is incorporated herein by reference.

### BACKGROUND

1. Technical Field

The present invention relates to a flip chip ball grid array (hereinafter referred to as “flip chip BGA”) board, and in particular, to a flip chip BGA board in which heat deformation is minimized by evenly removing the corners of a quadrilateral board.

2. Description of the Related Art

The conventional package —made by attaching a chip to a lead frame, connecting the pads of the chip with the leads, and sealing with resin —was large and heavy, and required a substantial length of wiring for its mounting. As a solution to these problems, the flip chip BGA package was developed, in which a chip is attached to an epoxy or ceramic board, and round solder balls are used as the leads.

The manufacturing method of a typical flip chip BGA package is described below with reference to FIGS. 1 (a) to (h).

(a) Aluminum pads 2 are formed on a semiconductor chip 1, and the semiconductor chip 1 is covered with a protective layer 3. (b) A metal layer 4 is formed by sputtering and is connected with the pads 2. (c) Photoresist 5 is applied so that only the regions of the pads 2 are exposed. (d) Lead coating 6 is applied on the regions of the pads 2 that are not masked by the photoresist 5. (e) The overlaying photoresist 5 is removed. (f) The metal layer 4 is removed by etching in the regions excluding the portions where the lead coating 6 is applied. (g) Heat is-applied to render the lead coating 6 a round form. (h) The bumped chip manufactured as above is joined to the flip chip BGA board 8. The joining method consists of depositing in a reflow device, heating the board 8 to a high temperature to melt the lead coating 6, and contacting the contact pads 10 of the flip chip BGA board 8 with the pads 2 of the chip 1. Then, resin is filled between the flip chip BGA board 8 and the chip 1 via an underfilling process.

As discussed above, the manufacture of a flip chip BGA entails the application of a large amount of heat, during the process of rounding the lead coating 6 as in (g) and during the reflow process as in (h). During the reflow process in particular, since it is needed to melt the lead coating 6, a high temperature generally of about 225 ° C. is applied, which causes warpage in the flip chip BGA board 8.

FIG. 2 is a perspective view of a conventional flip chip BGA package. The conventional flip chip BGA board 8 is generally formed as a quadrilateral.

FIG. 3 illustrates the degree of warpage developed on the flip chip BGA board 8 after manufacture. As seen in FIG. 3, the degree of warpage is the greatest at the edges of the flip chip BGA board 8, so that it is warped into a concave shape by heat. This warpage due to heat as illustrated in FIG. 3 is especially significant in a thin board such as a UTFCB (Ultra Thin Flexible Circuit Board) having a core thickness of 0.4 mm or less.

The thinner the flip chip BGA board 8, the greater is the degree of warpage. Thus, in spite of the recent trends toward boards with smaller sizes and more sophisticated functionalities, this warpage due to heat not only makes it difficult to mount the chip, but also causes the chip to be peeled off from the board. Also, this warpage becomes an obstacle to making thin boards.

### SUMMARY

As a solution to the foregoing problems of prior art, one aspect of the present invention provides a flip chip BGA board manufactured to be polygonal, rounded, or circular, to minimize deformation due to heat.

Additional aspects and advantages of the present invention will be set forth in part in the description which follows and, in part, will be obvious from the description, or may be learned by practice of the invention.

According to a first embodiment of the invention, a flip chip BGA board used in a flip chip BGA package may have comers of the board evenly removed to form a polygonal shape. Thus, by removing each comer of a conventional flip chip BGA board, the warpage of the board due to heat may be minimized. The board may be formed in a variety of shapes, such as a hexagonal or an octagonal shape.

In a second embodiment of the invention, a flip chip BGA board used in a flip chip BGA package may have comers of the board rounded in equal radii of curvature.

In a third embodiment of the invention, a flip chip BGA board used in a flip chip BGA package may be circular.

### BRIEF DESCRIPTION OF THE DRAWINGS

These and/or other aspects and advantages of the invention will become apparent and more readily appreciated from the following description of the embodiments, taken in conjunction with the accompanying drawings of which:

Figs. l(a) through 1(h) are cross-sectional views illustrating the manufacturing process of a typical flip chip BGA package.

FIG. 2 illustrates the distribution of warpage due to heat generated on a conventional board.

FIG. 3 illustrates the distribution of warpage due to heat generated on a conventional thin flip chip ball grid array board.

FIG. 4 is a schematic diagram illustrating a rounded flip chip ball grid array board based on an embodiment of the invention.

FIG. 5 is a schematic diagram illustrating a polygonal flip chip ball grid array board based on an embodiment of the invention.

FIG. 6 is a schematic diagram illustrating a circular flip chip ball grid array board based on an embodiment of the invention.

FIG. 7a illustrates the distribution of warpage due to heat generated on a rounded flip chip ball grid array board based on an embodiment of the invention.

FIG. 7b illustrates the distribution of warpage due to heat generated on a polygonal flip chip ball grid array board based on an embodiment of the invention.

FIG. 7c illustrates the distribution of warpage due to heat generated on a circular flip chip ball grid array board based on an embodiment of the invention.

### DETAILED DESCRIPTION

Hereinafter, the board with comers removed, according to embodiments of the present invention will be described in more detail with reference to the accompanying drawings.

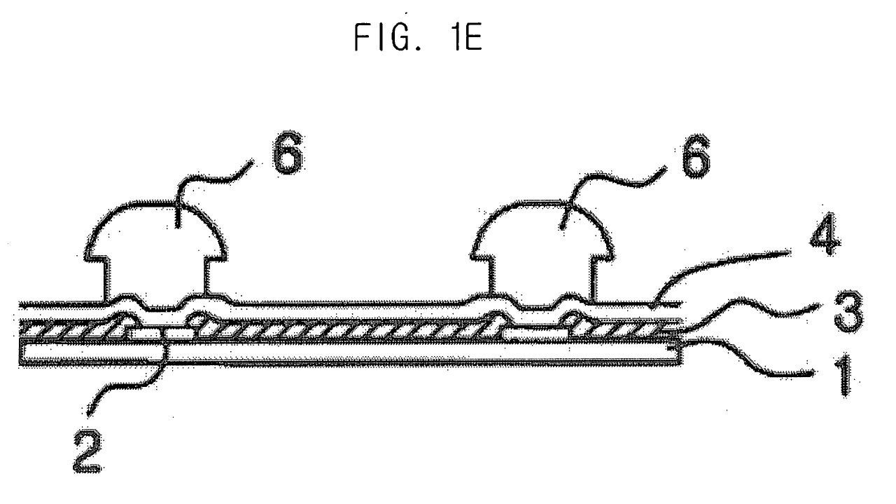

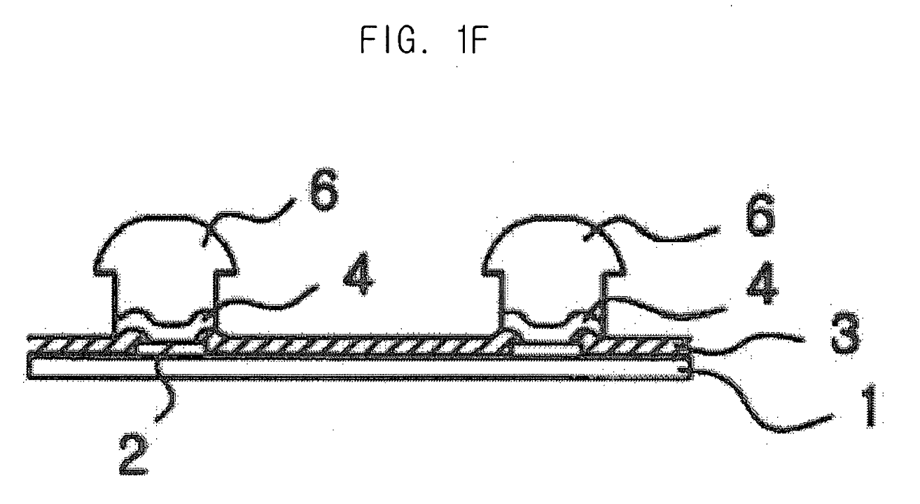

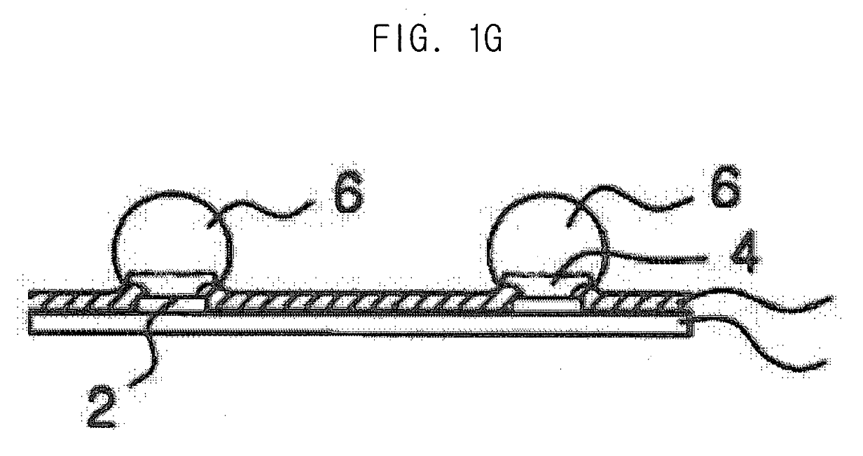

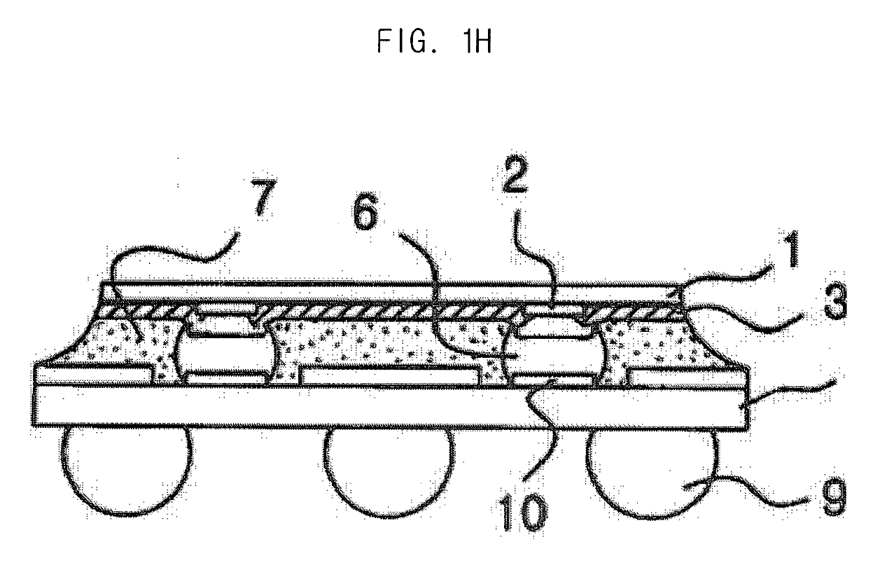

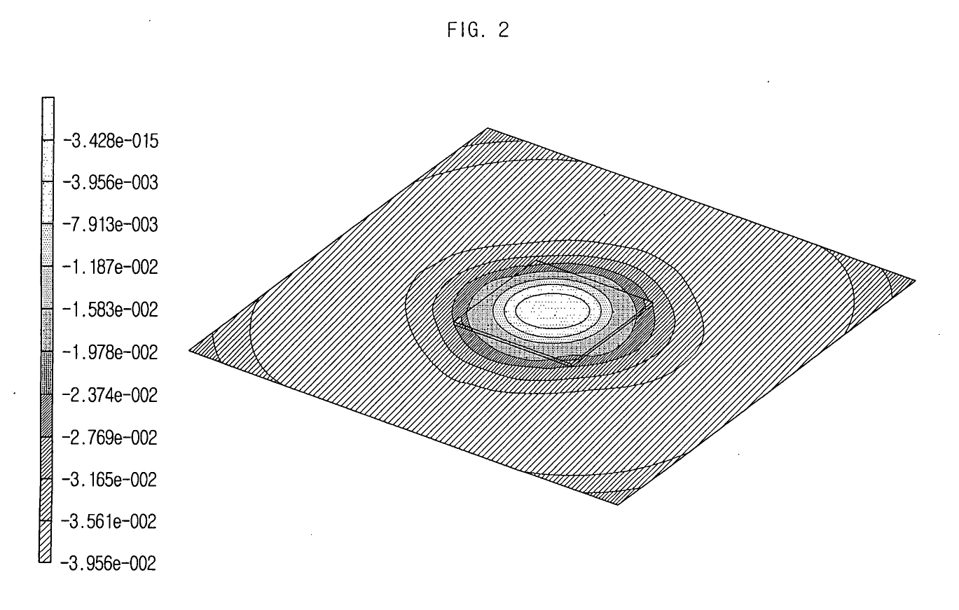

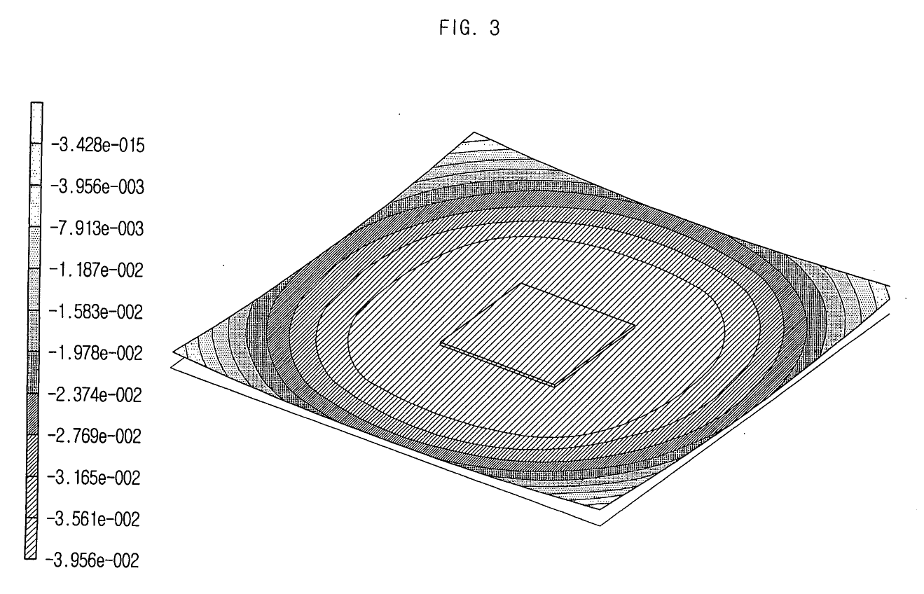

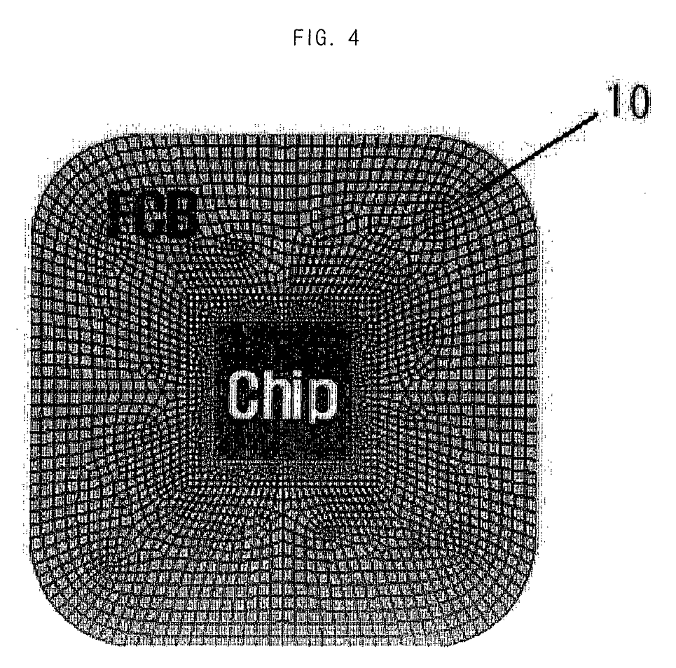

FIG. 4 illustrates a rounded flip chip BGA board 10, based on an embodiment of the invention. The flip chip BGA board 10 has each of the four comers rounded identically. It is preferable that the radius of curvature of each comer be made equal or very similar to prevent warpage due to heat as much as possible. Here, making the radii of curvature great, so that the board is as close as possible to a circle, most effectively prevents warpage, as will be explained with reference to experimental results described below. The flip chip BGA board 10 may be a board used in BOC (Board On Chip), CSP (Chip Scale Package), and UTFCB (Ultra Thin Flexible Circuit Board) technologies. Also, the board 10 may be formed in multiple layers of 6 layers or more.

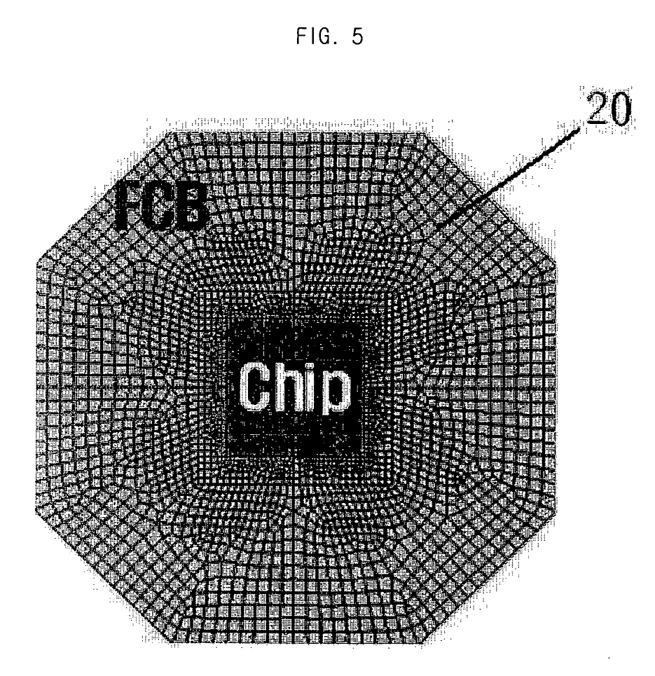

FIG. 5 illustrates a flip chip BGA board 20 having a polygonal shape, based on another embodiment of the invention. The flip chip BGA board 20 illustrated in FIG. 5 has a hexagonal shape. Of course, the invention is not limited to a hexagonal shape, and any shape may be used, such as an octagonal or a dodecagonal shape, such that the comers of the board are removed as much as possible to minimize deformation due to heat. Also, it is preferable to use a shape having as many sides as possible, so that the shape of the board is as close as possible to a circle.

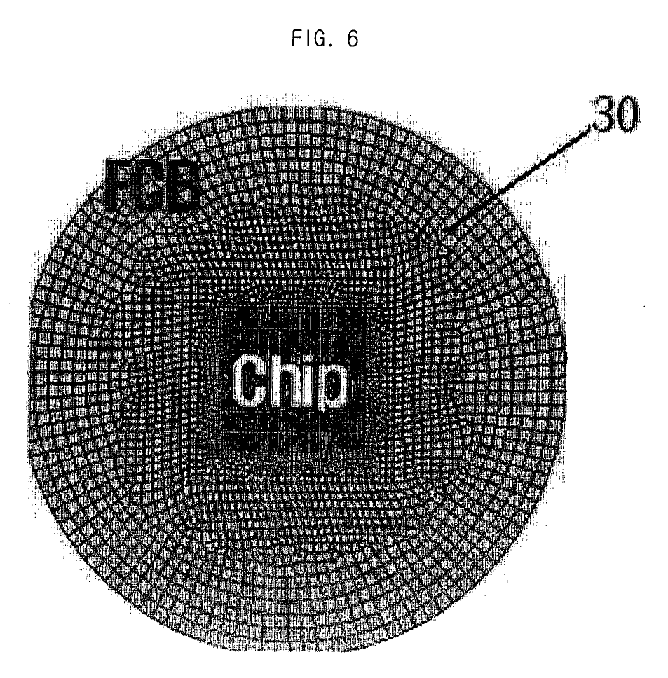

FIG. 6 illustrates a circular flip chip BGA board 30, based on another embodiment of the invention. As seen in FIG. 6, forming the board to have a circular shape removes the comers, so that warpage due to heat is minimized.

Typical methods of removing the comers of the flip chip BGA board 10, 20, 30 include using a saw or a router. In particular, in forming the flip chip BGA board 10, 20, 30 to have a polygonal, rounded, or circular shape as in the embodiments set forth above, a router may be preferable. Also, when the board is thin, it may be preferable to employ punching using a cast.

Hereinafter, warpage due to heat in the foregoing embodiments of the invention will be explained with reference to experimental results.

Experiment: Deformation due to heat according to the shape of the board

Experiment Conditions

Polymer type flip chip BGA's having a core thickness of 0.1 mm and dimensions of 37.5 mm ×37.5 mm were stacked in 6 layers, and the temperature was decreased from 175° C. to 25° C.

Experiment Cases 1 to 3

The warpage of the board according to changes in heat was measured, with a rounded flip chip BGA board 10 for Experiment Case 1, a polygonal flip chip BGA board 20 for Experiment Case 2, and a circular flip chip BGA board 30 for Experiment Case 3.

Comparison Example

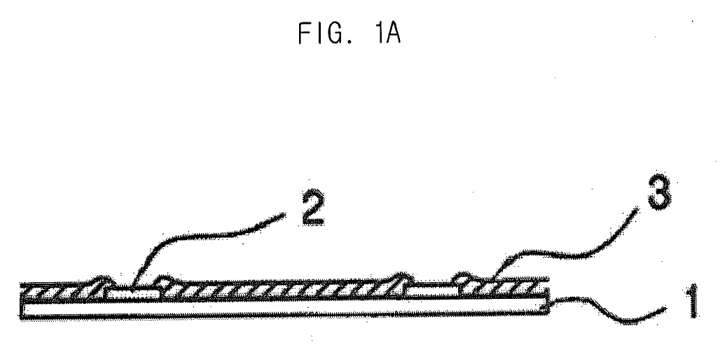

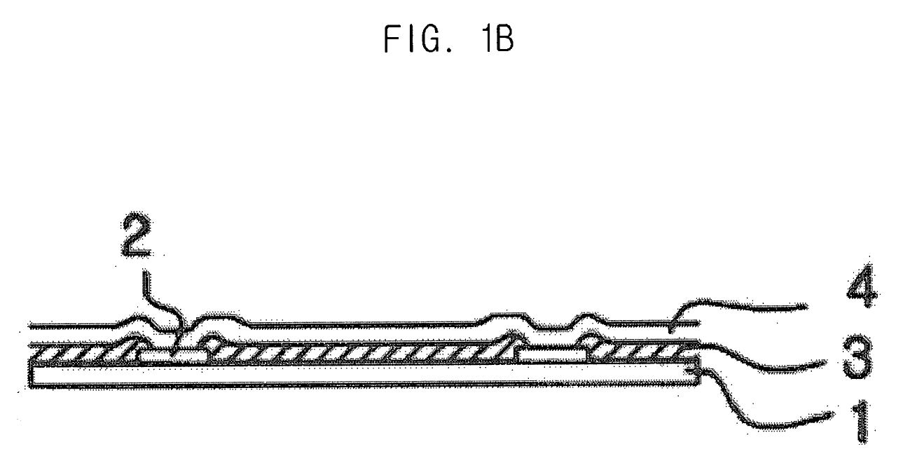

The warpage of the board due to heat was measured using a square flip chip BGA board such as that shown in FIG. 2.

Experiment Results

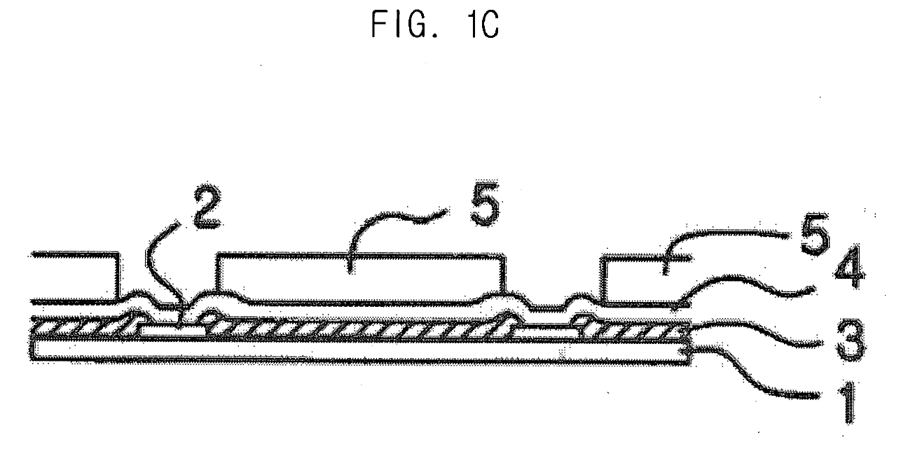

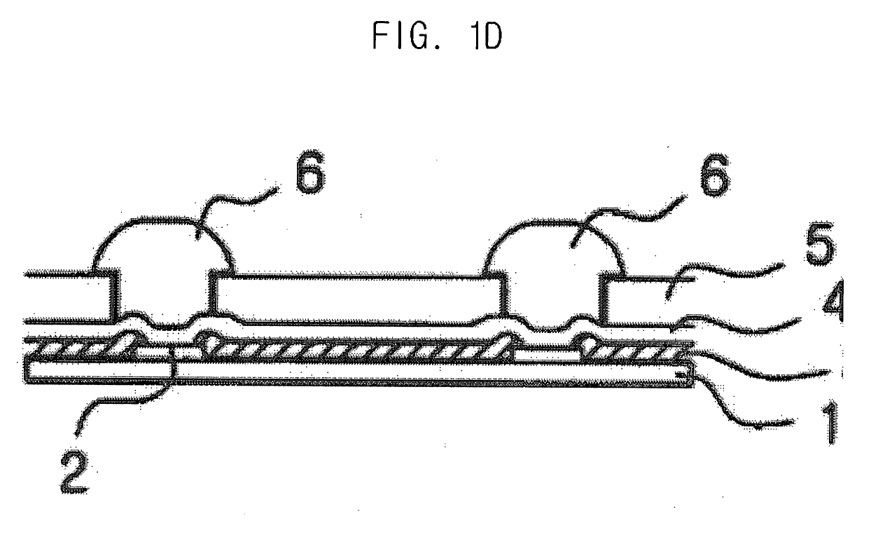

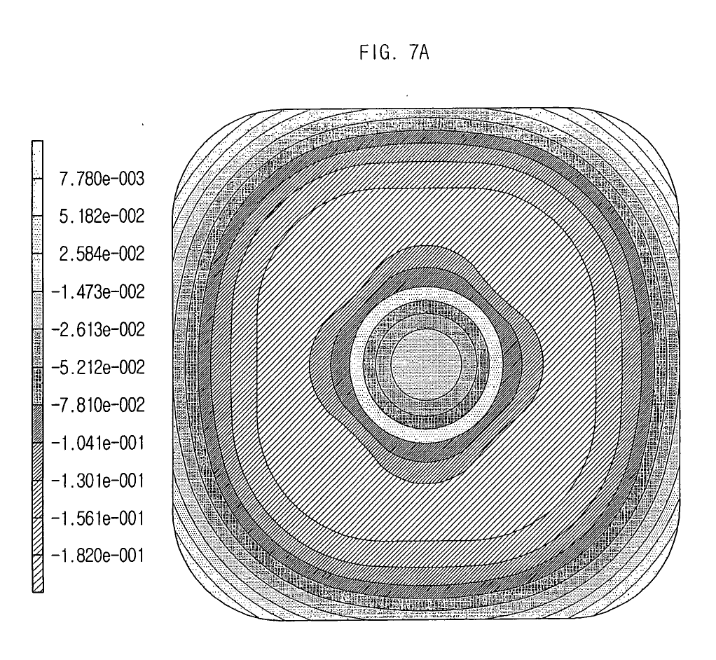

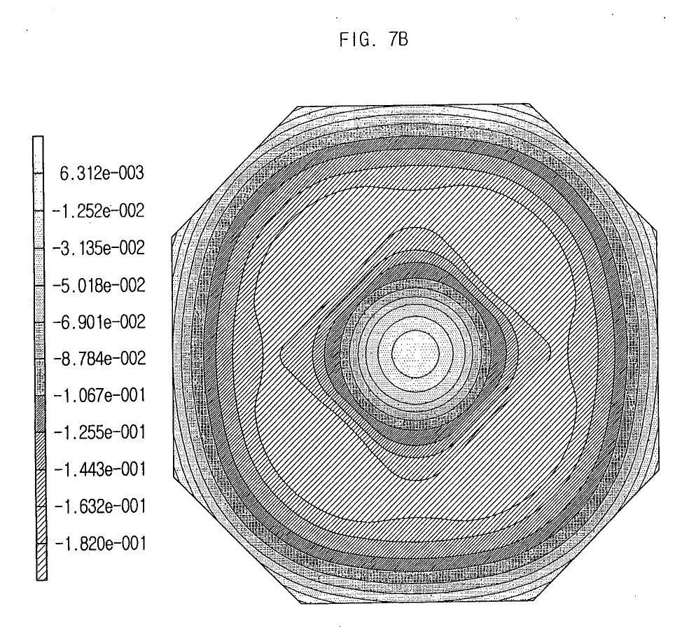

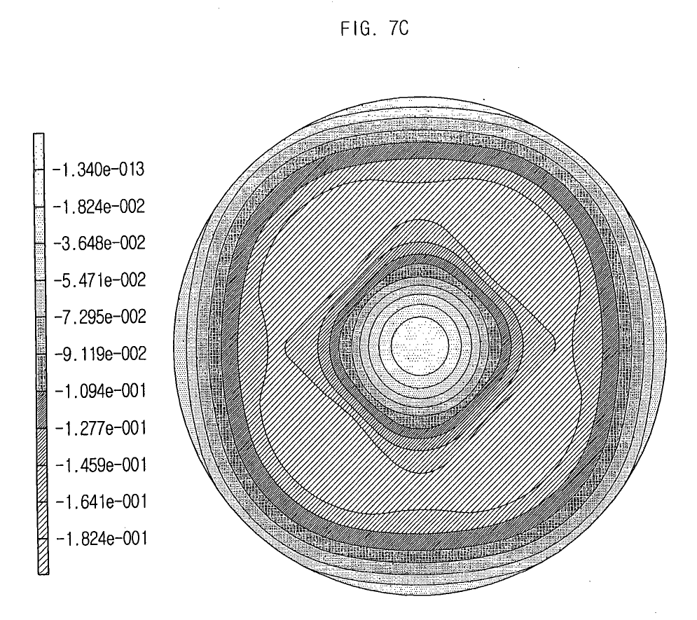

The warpage of the board in each Experiment Case is as illustrated in FIGS. 7a to 7c. The warpage due to heat of a conventional board according to the Comparison Example is as illustrated in FIG. 3. In FIG. 3 and FIGS. 7a to 7c, the (+) sign represents warpage of the board in the upward direction, and the (−) sign represents warpage of the board in the downward direction.

As in the Comparison Example illustrated in FIG. 1, for a conventional quadrilateral board, warpage is developed principally in each of the comers.

Referring to FIGS. 7a to 7c, there is less deformation due to heat in a polygonal board (Experiment Case 2) than in a rounded board (Experiment Case 1). Also, there is less deformation due to heat in a circular board (Experiment Case 3) than in a polygonal board (Experiment Case 2).

The relative percentages of warpage of Experiment Cases 1 to 3 with respect to that of the Comparison Example is listed below in Table 1.

TABLE 1

| | Degree of Warpage in Relation to |
|---|---|
| Shape of Board | Quadrilateral Board |
| Rounded (Experiment Case 1) | 17.81% |
| Polygonal (Experiment Case 2) | 13.05% |
| Circular (Experiment Case 3) | 12.61% |

As seen in Table 1, it is found that the degrees of warpage are decreased according to the degrees to which the corners of the boards are removed, from the rounded to the polygonal and to the circular boards.

According to the present invention comprised as above mentioned, a flip chip BGA board is provided in which the corners are evenly removed to minimize deformation due to heat.

With a flip chip BGA board based on the present invention, it is possible to produce thin boards since the deformation due to heat is minimized. Also according to the present invention, a flip chip BGA board may be provided which is high in reliability, since the risk of the chip being separated from the board is reduced.

Although a few embodiments of the invention have been shown and described, it will be appreciated by those skilled in the art that changes may be made in these embodiments without departing from the principles and spirit of the invention, the scope of which is defined in the appended claims and their equivalents.

What is claimed is:

1. A flip chip BGA board used in a flip chip BGA package, wherein corners of the board are evenly removed to form a polygonal shape.

2. The flip chip BGA board of claim 1, wherein the flip chip BGA board has a hexagonal shape.

3. A flip chip BGA board used in a flip chip BGA package, wherein the corners of the board are rounded in equal radii of curvature.

4. A flip chip BGA board used in a flip chip BGA package, wherein the board is circular.
